(19) United States
(12) Patent Application Publication
(10) Pub. No.: US 2023/0140999 A1
(43) Pub. Date: May 11, 2023

(54) AN APPARATUS FOR INDICATING A STATUS OF AN ELECTRICAL CABLE

(71) Applicant: VOLVO CONSTRUCTION EQUIPMENT AB, Eskilstuna (SE)

(72) Inventors: Michal CZERW, Wroclaw (PL); Piotr ZAMORSKI, Wroclaw (PL); Lukasz CZURA, Wroclaw (PL); Monika WAWRZYNIAK, Wroclaw (PL)

(21) Appl. No.: 17/769,365

(22) PCT Filed: Oct. 15, 2019
(86) PCT No.: PCT/EP2019/077846

§ 371 Date: Apr. 15, 2022

(51) Int. Cl. G01R 31/08; G01R 19/165; G01R 31/00

(52) U.S. Cl. CPC G01R 31/083; G01R 19/1659; G01R 31/006

(57) ABSTRACT

An apparatus and a method for indicating a status of an electrical cable, in particular in a power system of a vehicle the apparatus being configured to be attached to the electrical cable, the apparatus comprising:
voltage measuring means for continuously measuring a voltage level of the electrical cable,
at least one light-emitting indicator configured to be visibly attached to the electrical cable,
control means for controlling emission of light from the at least one light-emitting indicator based on the measured voltage of the electrical cable.
The apparatus is adapted to be powered by a power source other than the electrical cable.

### TECHNICAL FIELD

The invention relates to an apparatus for indicating a status of an electrical cable. The invention also relates to a power system and a vehicle, a working machine or a vessel. The invention further relates to a method for indicating a status of an electrical cable, a computer program, and a computer readable medium.

The invention can be applied in heavy-duty vehicles, such as trucks, buses and construction equipment. The invention can also be applied in working machines and vessels. Although the invention will be described with respect to a bus, the invention is not restricted to this particular vehicle, but may also be used in other vehicles such as trucks, trailers, wheel loaders, excavators, passenger cars, etc.

### BACKGROUND

Due to an ongoing electrification within the transport and construction equipment sectors, electric drive systems including e.g. batteries, electric motors/generators and various types of converters are becoming increasingly common in various types of vehicles, including heavy-duty vehicles. In order to gain sufficient power output for large machines, such electric drive systems are usually configured for delivering power at voltage levels which are higher in comparison to traditional vehicles, in which the batteries may deliver power at voltage levels of 12-24V DC. In electrified heavy-duty vehicles such as construction equipment or buses, a voltage level of 600V may typically be needed, and in electrically operated cars, a voltage level of 300V is common. Such voltage levels can cause electric shock and are therefore considered hazardous for humans.

Thus, there is a need for safety procedures and fail-safe systems to deal with the risks associated with such voltage levels on-board vehicles and construction equipment. Such procedures and systems have to some extent already been implemented, for example detailed commissioning/decommissioning procedures and technical measures such as high-voltage interlock loops (HVIL), insulation resistance monitoring devices, and insulated 600V circuits. However, personnel needing to deal with hybrid or electric machines are often stressed to work with potentially hazardous power systems and touch parts that were energised minutes ago.

US20170010311 discloses a device for indicating that an electrical connector used in mining equipment is safe to disconnect. The device comprises a driving circuit which is parasitically coupled to a conductor of the electrical connector, and an indicator providing a visual indication as to whether the conductor is energised or not.

However, electric drive systems used in automotive applications and construction machines include a lot of cabling, and the connectors may not be immediately possible to identify in case of e.g. an accident. In view of this, it would be desirable to provide reliable means for indicating whether an electrical cable is safe to touch or not.

### DEFINITIONS

An electrical cable is herein to be understood as an assembly of one or more elongated insulated conductors or wires for transmission of electrical power. The electrical cable may include one or more shielding layer(s). The term “cable” is herein used in short for “electrical cable”. The electrical cable may include e.g. two insulated conductors or wires configured to be at different voltage levels. For a direct current (DC) power source, the electrical cable may include one ground conductor or wire, and one positive or negative conductor or wire. For an alternating current (AC) power source, the electrical cable may either include one neutral conductor or wire and one phase conductor or wire, or three phase conductors or wires.

By “hazardous voltage” is herein intended a voltage level that may be considered harmful for humans. Voltage levels above 30V for DC voltage and above 12V for AC voltage are considered hazardous voltages.

### SUMMARY

A primary object of the invention is to provide an apparatus and a method for reliably indicating a status of an electrical cable that can be used in a power system of a heavy-duty vehicle, i.e. primarily for indicating whether the electrical cable is reliably safe to touch for humans, or not. In particular, it is an object to provide such an apparatus and method which can more reliably indicate whether the electrical cable is potentially hazardous to touch in situations such as accidents.

According to a first aspect of the invention, at least the primary object is achieved by an apparatus for indicating a status of an electrical cable according to claim 1. The apparatus is configured to be attached to the electrical cable, the apparatus comprising:
voltage measuring means for continuously measuring a voltage of the electrical cable,
at least one light-emitting indicator configured to be visibly attached to the electrical cable,
control means for controlling emission of light from the at least one light-emitting indicator based on the measured voltage of the electrical cable,

The apparatus is characterized in that it is adapted to be powered by a power source other than the electrical cable.

The status of the electrical cable may be e.g. “safe for humans” or “harmful for humans”, based on the measured voltage.

The apparatus is thus configured to emit light via the at least one light-emitting indicator in dependence on the measured voltage of the electrical cable.

Since the apparatus according to the invention is adapted to be powered by a power source other than the electrical cable, the light-emitting indicator(s) may emit light regardless of whether the electrical cable is energised or not. The characteristics of the emitted light, e.g. colour, i.e. wavelength, flashing pattern and intensity, depend on the measured voltage. In other words, the apparatus will reliably indicate a status of the electrical cable not only when the electrical cable is energised, but also when the cable is not energised. Thus, the invention enables distinction between a first case when the cable is safe to touch, and a second case when the apparatus itself is not working, since in the first case, light is emitted from the at least one light-emitting indicator, and in the second case, no light is emitted. This is in contrast to solutions in which the light-emitting indicator is powered via a parasitical coupling to the cable.

In order to be adapted to be powered by a power source other than the electrical cable, the apparatus may comprise connection means for electrical connection of a power source other than the electrical cable for powering the apparatus. Thus, the apparatus, including the voltage measuring means and the control means, or an electronic control unit comprising those means, and the at least one light-emitting indicator, may be powered by the power source. The power source may be a battery, such as an internal battery for mounting within a housing of the apparatus, or an external battery which may be connected to the apparatus. The power source may be a Li-Ion battery, e.g. a 15 V Li-Ion battery. The power source may also be an external vehicle battery, e.g. a 12 V external vehicle battery. The power source may also be a hazardous voltage battery to which the electrical cable is connected, such as a 600 V DC battery, in which case a DC/DC power converter is needed to reduce the voltage level. If the battery is the hazardous voltage battery, a DC link may be provided for connection to components of the apparatus.

The voltage measuring means may be at least one voltage sensor, such as a voltage probe, for example a voltage probe in the form of a bipolar sensor.

The at least one light-emitting indicator may comprise at least one light-emitting diode, or preferably at least two light-emitting diodes (LEDs) configured to emit light of different colour. The at least one light-emitting indicator may also comprise indicator(s) including fluorescent material that can be energised and thereby emit light, and/or any other indicator(s) which is/are able to emit light when energised.

The at least one light-emitting indicator is visibly attached to the electrical cable, meaning that it is attached to the cable in such a way that the light emitted therefrom is clearly visible upon inspection of the cable. The at least one light-emitting indicator may e.g. be mounted on a cable harness comprising the electrical cable whose voltage is measured, or it may be mounted inside or moulded into a transparent hose of the cable.

The at least one light-emitting indicator may be configured so that light may be emitted along a length of the electrical cable. In contrast to solutions in which energisation of a connector is indicated, the status of the cable may thus be reliably indicated along a length of the cable, i.e. along a longitudinal central axis of the cable. This is particularly advantageous for long cables. It is also valuable in case of accidents, when loose ends of energised and potentially harmful cables may be present, and a connector may not be immediately identifiable. Since the light-emitting indicator(s) will emit light indicating the status of the cable along its length, it is immediately apparent whether the cable is safe to touch or not.

The at least one light-emitting indicator may comprise a plurality of light-emitting indicators configured to be mounted along the electrical cable. Thus, reliable emission of light along the length of the cable is ensured. The plurality of light-emitting indicators may e.g. be in the form of light-emitting diodes (LEDs). For example, LED tape may be used, or LEDs may be arranged inside a transparent jacket of the electrical cable or of a cable harness including the electrical cable. Light may thereby be emitted along a length of the cable. The plurality of light-emitting indicators may all be of the same type, or they may be of different types. For example, the plurality of light emitting indicators may comprise a first set of light-emitting indicators configured for emitting light of a first colour, i.e. of a first wavelength, and a second set of light-emitting indicators configured for emitting light of a second colour, i.e. of a second wavelength. The control means may herein be configured to control either the first set or the second set to emit light, in dependence on the measured voltage. For example, this may be the case if LEDs are used. LEDs provide a reliable and energy efficient means for emission of light.

The voltage measuring means may comprise at least two voltage probes for measuring a voltage between at least two conductors of the electrical cable, the control means being configured to control the emission of light from the at least one light-emitting indicator based on the measured voltage between the conductors. The two conductors of the electrical cable may e.g. be a positive conductor and a ground conductor, or a neutral conductor and a phase conductor. Thus, it can be indicated whether it is associated with danger to simultaneously touch the conductors in e.g. isolated ground circuits commonly used in vehicle power systems.

The voltage measuring means may be configured to contact a conductor of the electrical cable at a non-shielded portion of the conductor, and the apparatus may further comprise a shield configured to electromagnetically shield the non-shielded portion of the conductor when the apparatus is attached to the electrical cable. A reliable voltage measurement may thereby be achieved without risking problems originating from electromagnetic interference (EMI) with surrounding electrical equipment.

The apparatus may comprise at least one electronic control unit configured to control the voltage measuring means and the emission of light from the at least one light-emitting indicator. To this end, the electronic control unit may be configured for measuring a voltage of the electrical cable, e.g. a voltage between conductors of the cable, and for controlling the at least one light-emitting indicator based on the measured voltage of the electrical cable. Thus, in this case, the electronic control unit comprises the control means for controlling emission of light and the voltage measuring means.

The apparatus may comprise at least two such electronic control units configured to work in redundancy. This ensures functionality also if one of the electronic control units is damaged.

The control means may be configured to control at least one of a colour, an intensity and a flashing pattern of light emitted from the at least one light-emitting indicator based on the measured voltage of the electrical cable. Preferably, at least a colour, i.e. a wavelength, and a flashing pattern are controlled, e.g. by using a steady green light to signal that the measured voltage is below a predefinable threshold level, and a blinking red light to signal that the measured voltage is above a predefinable threshold level. This ensures that colour blind people are able to distinguish between safe and potentially hazardous voltage levels. Moreover, the intensity and/or a flashing frequency may be adjusted in dependence on the measured voltage, e.g. by increasing the intensity and/or the flashing frequency with increasing voltage.

The control means may be configured to determine the status of the electrical cable based on the measured voltage thereof to one of at least a first status and a second status, wherein the first status is associated with a measured voltage below a predefinable threshold level or within a first predefinable range, and the second status is associated with a measured voltage above the predefinable threshold level or within a second predefinable range, wherein the control means is further configured to control the emission of light based on the determined status. Hereby, it becomes easy to distinguish between statuses, e.g. “harmful” and “safe”, associated with different measured voltage levels.

More than two statuses may be predefinable, wherein each status is associated with a predefinable voltage range, allowing distinction between more than two voltage ranges.

According to an example, if e.g. LEDs are used as light-emitting indicators, a first set of light-emitting indicators, configured to emit light of a first colour, may e.g. be controlled to an OFF state if the voltage is below the threshold level, and to an ON state if the voltage is above the threshold level, while a second set of light-emitting indicators, configured to emit light of a second colour, may be controlled to an ON state if the voltage is below the threshold level, and to an OFF state if the voltage is above the threshold level. The ON state may herein be understood to also include various flashing patterns, in addition to steady light emission.

The threshold level may preferably be set to a voltage level considered to be safe for humans, i.e. a voltage level which is below a hazardous voltage that may lead to electrical shock. The threshold level may be set to different voltage levels depending on whether the electrical cable is used for direct current (DC) voltage or alternating current (AC) voltage power transmission. For example, a threshold level of 30V for DC voltage and a threshold level of 12V for AC voltage may be set, which levels are usually considered as safe voltage levels in wet conditions. Likewise, the first predefinable range may be set to e.g. 0-12 V for AC voltage and to 0-30 V for DC voltage.

Each one of the at least first and second statuses may be associated with the emission of light of at least one of a predefinable distinguishing colour, a predefinable distinguishing intensity and a predefinable distinguishing flashing pattern. In other words, for each one of the at least first and second statuses, the control means may be configured to control the at least one light-emitting indicator to emit light of at least one of a predefinable colour, a predefinable intensity and a predefinable flashing pattern. It will thereby be easy to distinguish between the different statuses. Preferably, each one of the at least first and second statuses are associated with the emission of light of at least a predefinable distinguishing colour and a predefinable distinguishing flashing pattern in order to facilitate distinguishing between the statuses.

The apparatus may further comprise current measuring means for measuring an electric current of the electrical cable. This enables current measurement for diagnostic purposes. The current measuring means may e.g. be in the form of a Rogowski coil, a shunt based current sensor, or a clamp-on current probe.

The apparatus may further comprise a signal interface for communicating data to and/or from the apparatus, such as data relating to the status of the electrical cable. This allows communication and merging with e.g. on-board electromobility electronic control units such as other safety systems etc. The signal interface may be configured for communicating via a Controller Area Network (CAN) bus.

According to a second aspect of the invention, at least the primary object is also achieved by a cable assembly comprising an electrical cable and an apparatus according to the first aspect, wherein the at least one light-emitting indicator is attached to the electrical cable and wherein the voltage measuring means is configured for measuring a voltage of the electrical cable.

Advantages and effects provided by the cable assembly are largely analogous to the advantages and effects provided by the first aspect of the invention. It shall also be noted that each embodiment of the second aspect of the invention is applicable with each embodiment of the other aspects of the invention and vice versa.

According to a third aspect of the invention, at least the primary object is also achieved by an energy storage system comprising at least one power source and at least one cable assembly according to the second aspect connected to the at least one power source.

The energy storage system may e.g. form part of an electric drive system, such as an electric propulsion system, of a vehicle, a vessel or a working machine.

The power source may be an AC power source, e.g. a generator connected to e.g. an internal combustion engine or similar, or a DC power source, including e.g. batteries, capacitors, supercapacitors, and/or fuel cells. The energy storage system may further comprise a power converter/inverter assembly. Various electric systems and devices, such as an electric traction motor, a lighting system, an audio system, a hydraulic pump, or other auxiliary systems, may be connected to the energy storage system and receive AC or DC power output therefrom.

Advantages and effects provided by the energy storage system are largely analogous to the advantages and effects provided by the first aspect of the invention. It shall also be noted that each embodiment of the third aspect of the invention is applicable with each embodiment of the other aspects of the invention and vice versa.

According to a fourth aspect of the invention, at least the primary object is also achieved by a vehicle or a working machine or a vessel comprising an apparatus according to the first aspect and/or a cable assembly according to the second aspect and/or an energy storage system according to the third aspect. The vehicle or vessel or working machine may be fully electrified or it may be driven by a hybrid drive system, comprising both an electric motor and a combustion engine.

Advantages and effects provided by the vehicle or vessel or working machine are largely analogous to the advantages and effects provided by the first aspect of the invention. It shall also be noted that each embodiment of the fourth aspect of the invention is applicable with each embodiment of the other aspects of the invention and vice versa.

According to a fifth aspect of the invention, at least the primary object is also achieved by a method for indicating a status of an electrical cable according to the independent method claim. The method comprises:
continuously measuring a voltage of the electrical cable,
controlling emission of light from at least one light-emitting indicator based on the measured voltage of the electrical cable, the at least one light-emitting indicator being visibly attached to the electrical cable,

wherein a power for measuring the voltage and for controlling the emission of light is obtained from a power source other than the electrical cable.

Advantages and effects provided by the method are largely analogous to the advantages and effects provided by the first aspect of the invention. It shall also be noted that each embodiment of the fifth aspect of the invention is applicable with each embodiment of the other aspects of the invention and vice versa.

Controlling the emission of light from the at least one light-emitting indicator may comprise controlling at least one of a colour, an intensity and a flashing pattern of light emitted from the at least one light-emitting indicator based on the measured voltage of the electrical cable.

Controlling the emission of light from the at least one light-emitting indicator may comprise:
determining the status of the electrical cable based on the measured voltage thereof to one of at least a first status and a second status, wherein the first status is associated with a measured voltage below a predefinable threshold level or within a first predefinable range, and the second status is associated with a measured voltage above the predefinable threshold level or within a second predefinable range,
controlling the emission of light from the at least one light-emitting indicator based on the determined status.

According to a sixth aspect of the invention, at least one of the above defined objects is achieved by a computer program comprising program code means for performing the steps of the method according to the fifth aspect when said computer program is run on a computer.

According to a seventh aspect of the invention, at least one of the above defined objects is achieved by a computer readable medium carrying a computer program comprising program code means for performing the steps of the method according to the fifth aspect when said computer program is run on a computer.

Further advantages and advantageous features of the invention are disclosed in the following description and in the dependent claims.

### BRIEF DESCRIPTION OF THE DRAWINGS

With reference to the appended drawings, below follows a more detailed description of embodiments of the invention cited as examples.

In the drawings:

FIG. 1 is a perspective view of a vehicle according to an embodiment of the invention,

FIG. 2 is a perspective view of a power system including an apparatus according to an embodiment of the invention,

FIG. 3 is a perspective view of an apparatus according to an embodiment of the invention,

FIG. 4 is a schematic view of the apparatus according to an embodiment of the invention, and

FIG. 5 is a flow chart illustrating a method according to an embodiment of the invention.

The drawings show diagrammatic exemplifying embodiments of the present invention and are thus not necessarily drawn to scale. It shall be understood that the embodiments shown and described are exemplifying and that the invention is not limited to these embodiments. It shall also be noted that some details in the drawings may be exaggerated in order to better describe and illustrate the invention. Like reference characters refer to like elements throughout the description, unless expressed otherwise.

### DETAILED DESCRIPTION OF EXAMPLE EMBODIMENTS OF THE INVENTION

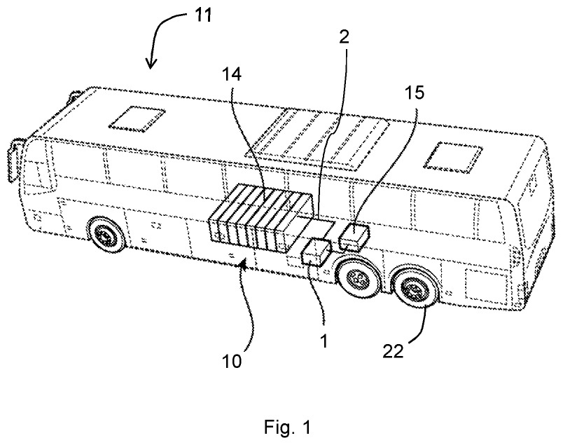

FIG. 1 schematically depicts a motor vehicle 11 in the form of an electrically operated bus. The bus is an example of a vehicle in which an apparatus 1 according to embodiments of the invention may be applied. The vehicle 11 comprises a schematically illustrated energy storage system 10 connected to an electric motor (not shown) for propelling drive wheels 22 of the vehicle 11. The energy storage system 10 includes a battery 14 comprising a plurality of battery units, an electrical cable 2 connecting the battery 14 to a power converter/inverter assembly 15, and an apparatus 1 for indicating a status of the electrical cable 2. The energy storage system 10 forms part of an electric propulsion system of the vehicle 11.

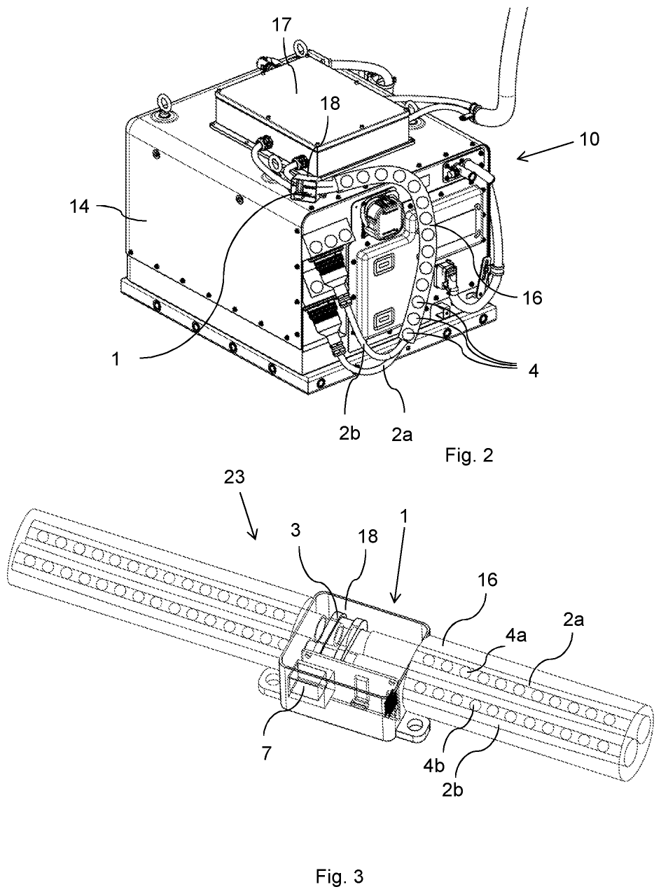

A 600 V battery 14 and a pre-charge device 17 for use in a vehicle or working machine is shown in FIG. 2. The pre-charge device 17 is connected to the battery 14 by means of two electrical cables 2a, 2b, which are herein bound together in a cable harness 16. An apparatus 1 for indicating a status of the electrical cables 2a, 2b is furthermore provided, i.e. for indicating whether any one of the cables 2a, 2b is energised by a potentially hazardous voltage level or not. The apparatus 1 has a housing 18 mounted around the cables 2a, 2b and attached to a casing of the battery 14. The apparatus 1 includes a plurality of light-emitting indicators 4 that are visibly attached to the cable harness 16. The light-emitting indicators 4 are configured to emit light indicating the status of the electrical cables 2a, 2b based on a measured voltage level thereof as will be further explained below.

FIG. 3 shows a cable assembly 23 including an apparatus 1 according to an embodiment of the invention and two electrical cables 2a, 2b, bound together in a cable harness 16. The cables 2a, 2b may in this case be connected to e.g. a 600 V DC power source of a vehicle, in which case one of the cables 2a may be at a voltage level of +600 V, and the other cable 2b is ground, i.e. at a 0 V voltage level. In the shown embodiment, the cable harness 16 comprises a transparent hose inside which the cables 2a, 2b extend. The apparatus 1 includes a housing 18, mounted around the cables 2a, 2b, which housing 18 is configured to be attached to e.g. a battery casing by means of fastening elements (not shown), similarly to what is shown in FIG. 1. The apparatus 1 further comprises voltage measuring means 3 for continuously measuring a voltage level between the respective electrical cables 2a, 2b. The voltage measuring means 3 is controlled by an electronic control unit 7. In this case, the voltage measuring means 3 comprises two voltage probes, such that a voltage level between the cables 2a, 2b can be determined, thereby determining if it would be hazardous to touch the cables.

Two sets of light-emitting indicators 4a, 4b are provided, each set of light-emitting indicators 4a, 4b being mounted on and along the respective electrical cable 2a, 2b. In the shown embodiment, the sets of light-emitting indicators 4a, 4b are provided as LED strips attached to the electrical cables 2a, 2b. The electronic control unit 7 is adapted for controlling emission of light from the two sets of light-emitting indicators 4a, 4b based on the measured voltage level between the electrical cables 2a, 2b. Thus, the emission of light from the two sets of light-emitting indicators 4a, 4b is controlled based on the same measured voltage level between the cables 2a, 2b.

The apparatus 1, including the voltage measuring means 3, the electronic control unit 7 and the light-emitting indicators 4a, 4b, is configured to be powered by a power source other than the electrical cables 2a, 2b. In other words, the apparatus 1 is not parasitically coupled to the cables 2a, 2b. Instead, another power source (not shown in FIG. 3) is provided. For this purpose, the apparatus 1 comprises connection means (not shown) for connecting a power source such as an external or internal battery (not shown).

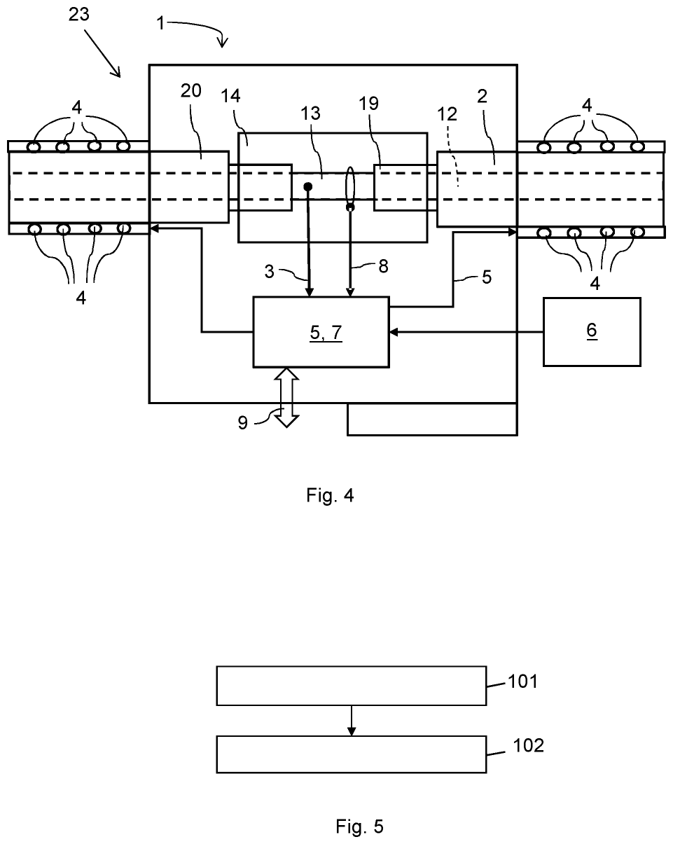

Reference is now also made to FIG. 4, schematically showing an apparatus 1 for indicating the status of an electrical cable 2 in further detail. For simplicity, only one elongated conductor 12 of the electrical cable 2 is shown in FIG. 4, although it is to be understood that this cable 2 typically includes a set of at least two insulated conductors, which may be in the form of separate cables such as shown in FIG. 3. The cable 2 may e.g. include a ground conductor and a “live” conductor for a DC power source, or a phase conductor and a neutral conductor for an AC power source, or alternatively three phase conductors for an AC power source. Around the elongated conductor 12, a shielding layer 19, protecting against electromagnetic interference (EMI), and an electrically insulating layer 20, are provided. The voltage measuring means 3, comprising a voltage probe, is in contact with a non-shielded portion 13 of the conductor 12. A separate shield 14, enclosing the non-shielded portion 13, is provided. The shield 14 is configured to electromagnetically shield the non-shielded portion 13 of the conductor 12 when the apparatus is attached to the electrical cable 2. A current measuring means 8 in the form of a Rogowski coil is positioned around the non-shielded portion 13 of the conductor 12. The voltage measuring means 3 and the current measuring means 8 are both connected to and controlled by an electronic control unit 7. The set of light-emitting indicators 4 are also connected to the electronic control unit 7 such that a control means 5 for controlling the emission of light from the light-emitting indicators 4 based on the voltage of the electrical cable 2, i.e. a measured voltage between the conductors 12 forming part of the electrical cable 2, is provided. The electronic control unit 7, and thereby also the voltage measuring means 3, the control means 5, the current measuring means 8 and the light-emitting indicators 4, are powered by a power source 6 in the form of a battery. The power source 6 may be placed inside a housing of the apparatus 1 or provided separately. A signal interface 9 for communicating data to and/or from the electronic control unit 7 is also provided.

Two electronic control units 7 configured to work in redundancy may be provided, such that the fail-safe arrangement is achieved.

The control means 5, i.e. the electronic control unit 7, is configured to control a colour and/or an intensity and/or a flashing pattern of light emitted from the light-emitting indicators 4 based on the voltage of the electrical cable 2, i.e. the measured voltage between the conductors 12.

The electronic control unit 7 is in the shown embodiment configured to determine the status of the electrical cable 2 based on the measured voltage between the conductors 12 thereof (of which only one is shown in FIG. 4) to one of a first status and a second status. The first status, which may be labelled “safe”, is associated with a measured voltage below a predefinable threshold level. For example, a threshold level of 30 V for DC voltage and a threshold level of 12 V for AC voltage may be set, which levels are usually considered as safe voltage levels in wet conditions. The second status, which may be labelled “hazardous”, is associated with a measured voltage above the predefinable threshold level. The electronic control unit 7 is configured to control the emission of light from the light-emitting indicators 4 based on the determined status. The first status is associated with the emission of light of a first distinguishing colour, such as green, and a first distinguishing flashing pattern, such as steady, i.e. non-flashing. The second status is associated with the emission of light of a second distinguishing colour, such as red, and a second distinguishing flashing pattern, such as blinking. The intensity of the light, and/or the blinking frequency, may also be set to vary with the measured voltage. For example, the intensity and/or blinking frequency may be set to increase with increasing voltage.

A method according to an embodiment of the invention is illustrated in FIG. 5. An apparatus 1 attached to at least one electrical cable 2 as described above is used in the method.

In a first step 101, a voltage of the electrical cable 2 is continuously measured by means of the voltage measuring means 3.

In a second step 102, the emission of light from the at least one light-emitting indicator 4, 4a, 4b is controlled based on the measured voltage of the electrical cable 2 determined in the first step 101.

Power for measuring the voltage in the first step 101 and for controlling the emission of light in the second step 102 is obtained from a power source 6 other than the electrical cable 2.

According to an example, the electrical cable 2 as illustrated in FIG. 4 forms part of an energy storage system 10 such as illustrated in FIG. 2, including both a pre-charge device 17 and a hazardous voltage battery 14. The energy storage system 10 is connected to a power converter/inverter assembly 15 as shown in FIG. 1 configured for providing electrical power to drive an electric machine. The apparatus 1 is used for continuously monitoring the status of the electrical cable 2. At a first point in time, a pre-charge device switch is turned on, and a hazardous voltage of 600 V, which is well above a preset threshold level of 30 V, is applied. The cable 2 is thus energised. The voltage measuring means 3 measures a voltage above the threshold level and determines that the status of the cable 2 is the second status, i.e. “hazardous”. The control means 5 controls the light-emitting indicators 4 to emit red, blinking light. At a second later point in time, the pre-charge device switch is switched off to disconnect the battery 14, and the measured voltage starts to decrease. However, due to discharging of capacitors forming part of the power converter/inverter assembly 15, the measured voltage of the cable 2 may still be above the threshold level of 30 V for a certain time period, and the light-emitting indicators 4 continue to emit red, blinking light. As soon as the measured voltage decreases below the threshold level, the control means 5 controls the light-emitting indicators 4 to emit green, steady light.

The control functionality of the example embodiments may be implemented using existing computer processors, or by a special purpose computer processor for an appropriate system, incorporated for this or another purpose, or by a hardwire system. Embodiments within the scope of the present disclosure include program products comprising machine-readable medium for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. When information is transferred or provided over a network or another communications connection (either hardwired, wireless, or a combination of hardwired or wireless) to a machine, the machine properly views the connection as a machine-readable medium. Thus, any such connection is properly termed a machine-readable medium. Combinations of the above are also included within the scope of machine-readable media. Machine-executable instructions include, for example, instructions and data which cause a general purpose computer, special purpose computer, or special purpose processing machines to perform a certain function or group of functions.

It is to be understood that the present invention is not limited to the embodiments described above and illustrated in the drawings; rather, the skilled person will recognize that many changes and modifications may be made within the scope of the appended claims.

1. An apparatus for indicating a status of an electrical cable, the apparatus being configured to be attached to the electrical cable, the apparatus comprising:
voltage measuring means for continuously measuring a voltage of the electrical cable,
at least one light-emitting indicator configured to be visibly attached to the electrical cable,
control means for controlling emission of light from the at least one light-emitting indicator based on the measured voltage of the electrical cable,
characterized in that
the apparatus is adapted to be powered by a power source other than the electrical cable.

2. The apparatus according to claim 1, wherein the at least one light-emitting indicator is configured so that light may be emitted along a length of the electrical cable.

3. The apparatus according to claim 2, wherein the at least one light-emitting indicator comprises a plurality of light-emitting indicators configured to be mounted along the electrical cable.

4. The apparatus according to claim 1, wherein the voltage measuring means comprises at least two voltage probes for measuring a voltage between at least two conductors of the electrical cable, the control means being configured to control the emission of light from the at least one light-emitting indicator based on the measured voltage between the conductors.

5. The apparatus according to claim 1, wherein the voltage measuring means is configured to contact a conductor of the electrical cable at a non-shielded portion of the conductor, and wherein the apparatus further comprises a shield configured to electromagnetically shield the non-shielded portion of the conductor when the apparatus is attached to the electrical cable.

6. The apparatus according to claim 1, wherein the apparatus comprises at least one electronic control unit configured to control the voltage measuring means and the emission of light from the at least one light-emitting indicator, preferably wherein the apparatus comprises at least two such electronic control units configured to work in redundancy.

7. The apparatus according to claim 1, wherein the control means is configured to control at least one of a colour, an intensity and a flashing pattern of light emitted from the at least one light-emitting indicator based on the measured voltage of the electrical cable.

8. The apparatus according to claim 1, wherein the control means is configured to determine the status of the electrical cable based on the measured voltage thereof to one of at least a first status and a second status, wherein the first status is associated with a measured voltage below a predefinable threshold level or within a first predefinable range, and the second status is associated with a measured voltage above the predefinable threshold level or within a second predefinable range, and wherein the control means is further configured to control the emission of light based on the determined status.

9. The apparatus according to claim 8, wherein each one of the at least first and second statuses is associated with the emission of light of at least one of a predefinable distinguishing colour, a predefinable distinguishing intensity and a predefinable distinguishing flashing pattern.

10. The apparatus according to claim 1, further comprising current measuring means for measuring an electric current of the electrical cable.

11. The apparatus according to claim 1, further comprising a signal interface for communicating data to and/or from the apparatus.

12. A cable assembly comprising an electrical cable and an apparatus according to claim 1, wherein the at least one light-emitting indicator is attached to the electrical cable and wherein the voltage measuring means is configured for measuring a voltage of the electrical cable.

13. An energy storage system comprising at least one power source and at least one cable assembly according to claim 12 connected to the at least one power source.

14. A vehicle or a working machine or a vessel comprising an apparatus according to claim 1, a cable assembly comprising an electrical cable and an apparatus, wherein the at least one light-emitting indicator is attached to the electrical cable and wherein the voltage measuring means is configured for measuring a voltage of the electrical cable and an energy storage system comprising at least one power source and at least one cable assembly connected to the at least one power source.

15. A method for indicating a status of an electrical cable, the method comprising:
continuously measuring (101) a voltage of the electrical cable,
controlling emission of light from at least one light-emitting indicator based on the measured voltage of the electrical cable, the at least one light-emitting indicator being visibly attached to the electrical cable,
wherein a power for measuring the voltage and for controlling the emission of light is obtained from a power source other than the electrical cable.

16. The method according to claim 15, wherein controlling the emission of light from the at least one light-emitting indicator comprises controlling at least one of a colour, an intensity and a flashing pattern of light emitted from the at least one light-emitting indicator based on the measured voltage of the electrical cable.

17. The method according to claim 15, wherein controlling the emission of light from the at least one light-emitting indicator comprises:
determining the status of the electrical cable based on the measured voltage thereof to one of at least a first status and a second status, wherein the first status is associated with a measured voltage below a predefinable threshold level or within a first predefinable range, and the second status is associated with a measured voltage above the predefinable threshold level or within a second predefinable range,
controlling the emission of light from the at least one light-emitting indicator based on the determined status.

18. A computer program comprising program code performing the steps of claim 15, when said computer program is run on a computer.

19. A computer readable medium carrying a computer program comprising program code performing the steps of claim 15 when said computer program is run on a computer.
